(19) United States
(12) Patent Application Publication
(10) Pub. No.: US 2024/0021414 A1
(43) Pub. Date: Jan. 18, 2024

(54) SHOCK ABSORBING PLATE AND SUBSTRATE PROCESSING APPARATUS INCLUDING THE SAME

(71) Applicant: Samsung Electronics Co., Ltd., Suwon-si (KR)

(72) Inventors: Suhwan Park, Suwon-si (KR); Ohchel Kwon, Suwon-si (KR); Yongmyung Jun, Suwon-si (KR); Gwanwoo Min, Suwon-si (KR); Hyeongkwon Jeong, Suwon-si (KR)

(21) Appl. No.: 18/141,341

(22) Filed: Apr. 28, 2023

(30) Foreign Application Priority Data
Jul. 12, 2022 (KR) 10-2022-0085877

(51) Int. Cl. H01J 37/32

(52) U.S. Cl. CPC H01J 37/32477; H01J 37/32522; H01J 37/3244; H01J 2237/334

(57) ABSTRACT

A shock absorbing plate configured to absorb a shock between a first plate and a second plate stacked on the first plate in a vertical direction, positioned between the first plate and the second plate so that the first plate is apart from the second plate in the vertical direction, and having a circular shape when viewed in the vertical direction. When no pressure is applied to the shock absorbing plate, a vertical thickness of the shock absorbing plate is greatest at a center thereof and decreases from the center toward an outer edge thereof. A plurality of holes penetrate the shock absorbing plate in the vertical direction. A friction coefficient and an elastic modulus of the shock absorbing plate are less than a friction coefficient and an elastic modulus of each of the first plate and the second plate.

### CROSS-REFERENCE TO RELATED APPLICATION(S)

This application is based on and claims priority under 35 U.S.C. § 119 to Korean Patent Application No. 10-2022-0085877, filed on Jul. 12, 2022 in the Korean Intellectual Property Office, the disclosure of which is incorporated by reference herein in its entirety.

### BACKGROUND

The inventive concept relates to a shock absorbing plate and a substrate processing apparatus including the shock absorbing plate, and more particularly, to a shock absorbing plate preventing cracks and gas leakage due to thermal expansion between stacked plates in a processing chamber.

In manufacturing processes of a semiconductor device, an etching process of etching an etching target layer on a substrate is used. The etching process often includes heat treatment process inside the processing chamber. In the heat treatment process, the temperature inside the processing chamber rises and falls repeatedly, and in this case, plates in the processing chamber repeat expansion and contraction due to the temperature change.

As the plates expand and contract, friction occurs between the plates. Cracks and particle issues frequently occur on the surface of the plates due to the friction between the plates.

### SUMMARY

The inventive concept provides a shock absorbing plate preventing a surface scratch of a plate, which occurs due to expansion and contraction caused by a temperature change and preventing a leakage of gas passing through a center hole.

The inventive concept provides a substrate processing apparatus preventing a surface scratch of a plate, which occurs due to expansion and contraction caused by a temperature change and preventing a leakage of gas passing through a center hole.

In addition, the issues to be solved by the technical idea of the inventive concept are not limited to those mentioned above, and other issues may be clearly understood by those of ordinary skill in the art from the following descriptions.

According to an aspect of the inventive concept, there are provided a shock absorbing plate and a substrate processing apparatus including the same as described below.

A shock absorbing plate configured to absorb a shock between a first plate in a heat treatment chamber and a second plate stacked on the first plate in a vertical direction includes a plurality of holes between the first plate and the second plate so that the first plate is apart from the second plate in the vertical direction, the plurality of holes having a circular shape when viewed in the vertical direction, wherein a vertical thickness of the shock absorbing plate, when pressure is not applied to the shock absorbing plate, is greatest at a center thereof and decreases from the center toward an outer edge thereof, and the plurality of holes penetrate the shock absorbing plate in the vertical direction, wherein a friction coefficient of the shock absorbing plate is less than a friction coefficient of each of the first plate and the second plate, and an elastic modulus of the shock absorbing plate is less than an elastic modulus of the first plate and the second plate.

A substrate processing apparatus includes a substrate support configured to support a substrate, a lamp plate including a lower surface facing the substrate, an upper surface opposite to the lower surface of the lamp plate, and a plurality of lamps configured to heat the substrate, a shock absorbing plate including an upper surface contacting the lower surface of the lamp plate and a lower surface facing the upper surface of the shock absorbing plate, an upper shower head plate including an upper surface contacting the lower surface of the shock absorbing plate and a lower surface facing the upper surface of the upper shower head plate, and a lower shower head plate including an upper surface contacting the lower surface of the upper shower head plate, a lower surface opposite to the upper surface of the lower shower head plate and facing the substrate, and a plurality of spray holes configured to supply a gas onto the substrate. The shock absorbing plate is configured to absorb a shock between the lamp plate and the upper shower head plate in a vertical direction. Each of the lamp plate, the shock absorbing plate, the upper shower head plate, and the lower shower head plate further includes a center hole configured to pass the gas, a plurality of lamp holes configured to allow a plurality of lamps to pass therethrough, respectively, and a plurality of edge holes configured to allow a plurality of connection members to pass therethrough, respectively. The plurality of connection members are configured to hold together the lamp plate, the shock absorbing plate, the upper shower head plate, and the lower shower head plate. Each hole of the center hole, the plurality of lamp holes, and the plurality of edge holes extends from an upper surface to a lower surface of a corresponding plate.

A substrate processing apparatus includes a heat treatment chamber configured to provide a space for processing a substrate, a substrate support configured to support the substrate, a lamp plate including a lower surface facing a top surface of the substrate support, an upper surface opposite the lower surface of the lamp plate, and a plurality of lamps configured to heat the substrate, a shock absorbing plate including an upper surface contacting the lower surface of the lamp plate and a lower surface opposite the upper surface of the shock absorbing plate, an upper shower head plate including an upper surface contacting the lower surface of the shock absorbing plate and a lower surface opposite the upper surface of the upper shower head plate, and a lower shower head plate including an upper surface contacting the lower surface of the upper shower head plate, a lower surface opposite the upper surface of the lower shower head plate and the substrate, and a plurality of spray holes configured to supply a gas onto the substrate, wherein a friction coefficient of the shock absorbing plate is less than a friction coefficient of each of the lamp plate and the upper shower head plate, and an elastic modulus of the shock absorbing plate is less than elastic moduli of the first plate and the second plate. The shock absorbing plate is configured to absorb a shock between the lamp plate and the upper shower head plate in a vertical direction. A vertical thickness of the shock absorbing plate at a center thereof, when no pressure is applied to the shock absorbing plate, is greatest and decreases from the center toward an edge thereof.

### BRIEF DESCRIPTION OF THE DRAWINGS

Embodiments will be more clearly understood from the following detailed description taken in conjunction with the accompanying drawings in which:

FIG. 1 is a schematic view illustrating a substrate processing apparatus according to an embodiment;

FIG. 2 is a side cross-sectional view passing through the center of a lead unit of a substrate processing apparatus, according to an embodiment;

FIG. 3 is an exploded view of a lead unit according to an embodiment;

FIG. 4 is a plan view of a shock absorbing plate of a substrate processing apparatus, according to an embodiment;

FIG. 5 is a cross-sectional view of a shock absorbing plate taken along line V-V′ in FIG. 4 according to an embodiment;

FIG. 6 is a plan view of a shock absorbing plate of a substrate processing apparatus, according to an embodiment;

FIG. 7 is a cross-sectional view of a shock absorbing plate taken along line VII-VII′ in FIG. 6 according to an embodiment;

FIG. 8 is a schematic diagram of a shock absorbing plate according to an embodiment;

FIG. 9 is a schematic diagram of a shock absorbing plate according to an embodiment;

FIG. 10 is a plan view of a shock absorbing plate of a substrate processing apparatus, according to an embodiment; and

FIG. 11 is a cross-sectional view of a shock absorbing plate taken along line XI-XI′ in FIG. 10 according to an embodiment.

### DETAILED DESCRIPTION OF THE EMBODIMENTS

Hereinafter, embodiments of the inventive concept are described in detail with reference to the accompanying drawings. Identical reference numerals are used for the same constituent elements in the drawings, and duplicate descriptions thereof are omitted.

Hereinafter, in the drawings, an X-axis direction and a Y-axis direction may represent directions in parallel with the surface of a substrate W, and the X-axis direction and the Y-axis direction may include directions perpendicular to each other. A Z-axis direction may represent a direction perpendicular to the surface of the substrate W, and the Z-axis direction may include a direction perpendicular to an X-Y plane.

Hereinafter, in the drawings, a first horizontal direction, a second horizontal direction, and a vertical direction may be understood as follows. The first horizontal direction may be understood as the X-axis direction, the second horizontal direction may be understood as the Y-axis direction, and the vertical direction may be understood as the Z-axis direction.

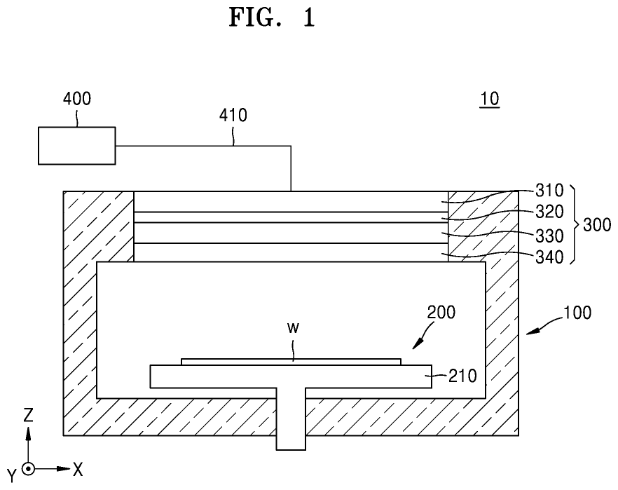

FIG. 1 is a schematic view of a substrate processing apparatus 10 according to an embodiment.

Referring to FIG. 1, the substrate processing apparatus 10 may include a processing chamber 100, a substrate support unit (e.g., a substrate support) 200 arranged on a bottom portion of the processing chamber 100, a lead unit 300 arranged on an upper portion of the processing chamber 100, and a gas storage unit 400 connected to the lead unit 300.

The processing chamber 100 may have an inner space of a certain size and include a material having good wear resistance and corrosion resistance. The processing chamber 100 may be referred to as a chamber housing. The processing chamber 100 may include, for example, an aluminum block, but is not limited thereto. The processing chamber 100 may be a portion of the substrate processing apparatus 10 including a plurality of processing chambers.

The substrate support unit 200 may be arranged on a bottom portion in the processing chamber 100. The substrate support unit 200 may include a support 210. The substrate W to be processed may be arranged on an upper surface of the support 210 (e.g., a substrate support, also described as a stage), and a rotatable shaft configured to rotate the substrate when placed on the support 210.

The substrate support unit 200 may function as a substrate support member capable of supporting the substrate W. The substrate support unit 200 may fix and support the substrate W during the process. The substrate support unit 200 may be formed by a combination of aluminum and ceramic, and may include a conductive unit capable of receiving electrostatic force from an electrostatic force supply source (not illustrated) and a protrusion unit of an irregular shape, which is polarizing.

When electrostatic force is applied between the substrate W and the support 210 by using bipolar electrostatic force supplied by the electrostatic force supply source, the substrate W may be stably fixed to the support 210 during the process. The protrusion unit of the irregular shape may be arranged on the support 210, and the substrate W may be fixed by using the bipolar electrostatic force. However, the substrate support unit 200 is not limited thereto, and for example, the substrate support unit 200 may fix the substrate W in various ways, such as a mechanical clamping.

The lead unit 300 may include a lamp plate 310, a shock absorbing plate 320 arranged on a lower surface of the lamp plate 310, an upper shower head plate 330 arranged on a lower surface of the shock absorbing plate 320, and a lower shower head plate 340 arranged on a lower surface of the upper shower head plate 330. The lead unit 300 may be apart at a position, where the lead unit 300 faces the substrate support unit 200 at a certain interval, and arranged on the upper portion of the processing chamber 100. The lead unit 300 may be connected to the gas storage unit 400 via a gas supply line 410, and the gas storage unit 400 may supply a process gas to the inner space of the processing chamber 100 via the gas supply line 410. The lead unit 300 is described in detail below.

The gas storage unit 400 may be connected to the lead unit 300 via the gas supply line 410. The gas supply line 410 may supply a process gas from the gas storage unit 400 to the lead unit 300, and may include a valve (not illustrated) for switching a gas flow. The process gas may contain, for example, argon (Ar), ammonia (NH₃), a fluorine (F)-based gas, or the like, but is not limited thereto.

The gas storage unit 400 may be controlled by a gas controller (not illustrated). For example, by controlling the gas storage unit 400, the gas controller may control the type of a gas, a supply starting time point/ending time point of the gas, a flow rate, or the like of the gas supplied to the lead unit 300.

In the substrate processing apparatus 10, while a plasma etching process is performed on not only the components but also the substrate W, an exhaust mean (not illustrated) for discharging reaction by-products or residual process gases of the etching process may be further arranged.

The substrate W, to be processed by the substrate processing apparatus 10, may have an active surface, on which a semiconductor device is formed, and may have an inactive surface facing the active surface. The active surface may correspond to a front-side surface of the substrate W, and the inactive surface may correspond to a back-side surface of the substrate W. In addition, the substrate W may include a wafer and a material layer for forming a semiconductor device formed on the active surface of the wafer. In some embodiments, the substrate W may be a semiconductor substrate including silicon, germanium, or silicon/germanium, a silicon-on-insulator (SOI) wafer, or a germanium-on-insulator (GOI) wafer.

In the etching process performed by the substrate processing apparatus 10, a treatment gas may be sprayed on the active surface of the substrate W, on which a particular layer material is formed, by using the lead unit 300, to soften the particular layer material, and the lead unit 300 may spray the etching gas to etch the particular layer material formed on the substrate W. Thereafter, to remove the by-products formed during the etching process, the lead unit 300 may heat the substrate W to create a high-temperature environment, and a blowing gas may be sprayed by using the lead unit 300 to remove the by-products from the surface of the substrate W. A series of processes described above may be referred to as one cycle, and then, by repeating the cycles, the etching process of the target layer of the substrate W may be performed.

However, as the cycles are repeated, the temperature inside the processing chamber 100 may repeat rising and falling, and the plates of the lead unit 300 including a metal, particularly, the lamp plate 310 and the upper shower head plate 330, may repeat expansion and contraction.

In a general substrate processing apparatus, the lamp plate 310 may be stacked directly on an upper surface of the upper shower head plate 330, and thus, friction due to the expansion and contraction caused by heat of the plates may occur on a surface, where the lamp plate 310 contacts the upper shower head plate 330, and issue of cracks and particles may occur. It will be understood that when an element is referred to as being “connected” or “coupled” to or “on” another element, it can be directly connected or coupled to or on the other element or intervening elements may be present. In contrast, when an element is referred to as being “directly connected” or “directly coupled” to another element, or as “contacting” or “in contact with” another element, there are no intervening elements present at the point of contact.

The substrate processing apparatus 10 according to the inventive concept may prevent friction between the lamp plate 310 and the upper shower head plate 330 and prevent leakage of the gas supplied to the substrate W, by arranging the shock absorbing plate 320 having physical properties and design described below between the lamp plate 310 and the upper shower head plate 330. In this manner, it may be possible to improve the productivity of the substrate processing apparatus 10.

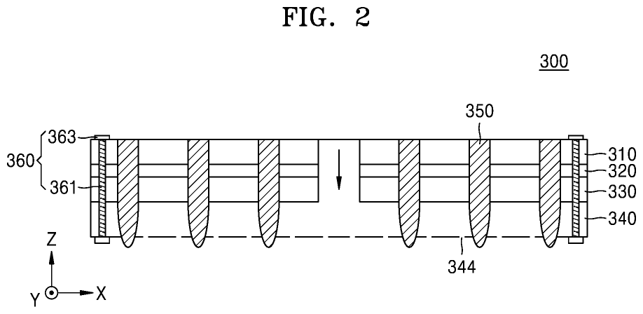

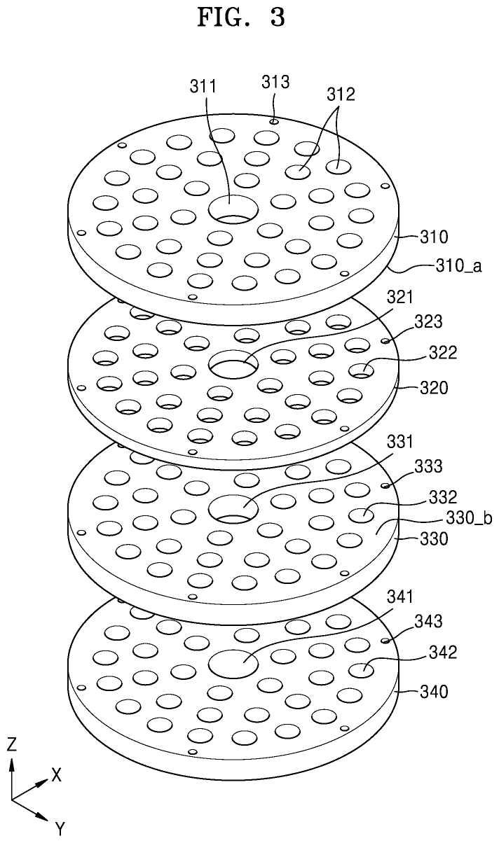

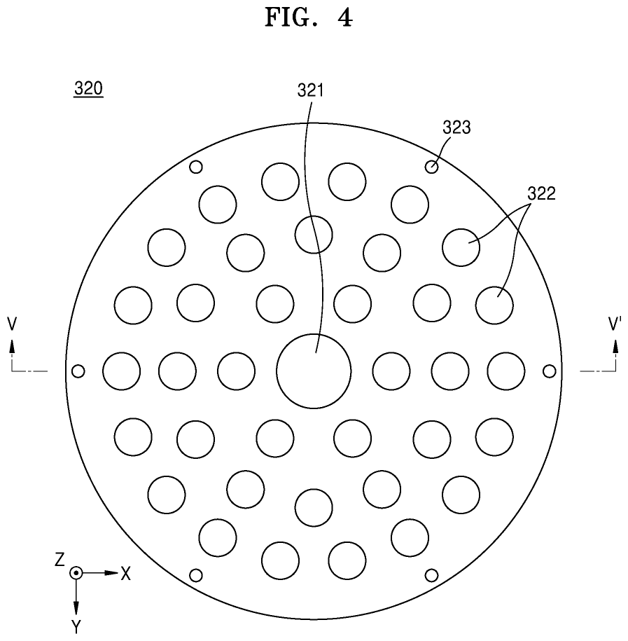

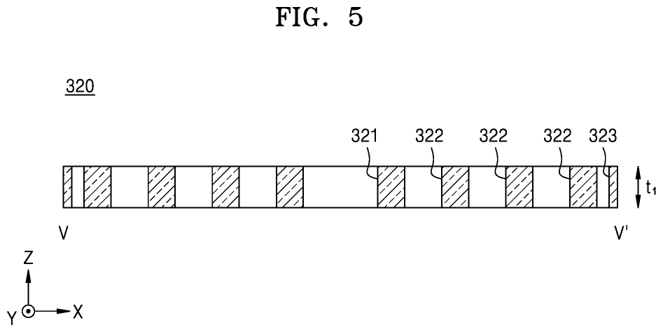

FIG. 2 is a side cross-sectional view passing through the center of the lead unit 300 of the substrate processing apparatus 10, according to an embodiment. FIG. 3 is an exploded view of the lead unit 300 according to an embodiment. FIG. 4 is a plan view of the shock absorbing plate 320 of the substrate processing apparatus 10, according to an embodiment. FIG. 5 is a cross-sectional view of the shock absorbing plate 320 taken along line V-V in FIG. 4 according to an embodiment.

Referring to FIGS. 2 through 5, the lead unit 300 may include a lamp 350, the lamp plate 310, the upper shower head plate 330, the lower shower head plate 340, the shock absorbing plate 320, and a connection member 360.

The lower shower head plate 340, the upper shower head plate 330, the shock absorbing plate 320, and the lamp plate 310 of the lead unit 300 may be stacked sequentially. The lower shower head plate 340 may be at the lowest end of the lead unit 300, the upper shower head plate 330 may be arranged on an upper surface of the lower shower head plate 340, the shock absorbing plate 320 may be arranged on the upper surface of the upper shower head plate 330, and the lamp plate 310 may be arranged on an upper surface of the shock absorbing plate 320. Side surfaces of the lower shower head plate 340, the upper shower head plate 330, the shock absorbing plate 320, and the lamp plate 310 of the lead unit 300 may be on the same plane.

The lamp 350 may include a body and a heating unit inside the body. The body may have a cylindrical shape extending in a vertical direction Z, but a lower end of the body may be thinner in a direction toward the substrate W. The lamp 350 may be attached to a portion of the lamp plate 310. The body may penetrate the lamp plate 310, the shock absorbing plate 320, the upper shower head plate 330, and the lower shower head plate 340. According to embodiments, the body may include quartz, but is not limited thereto. The heating unit may be configured to apply heat to the substrate W. According to embodiments, the heating unit may include a light source. The heating unit may increase temperature of the substrate W in the form of thermal radiation by projecting light toward the substrate W. According to embodiments, the lamp 350 may include a halogen lamp, but is not limited thereto. A plurality of lamps 350 may be provided in the lead unit 300. In some embodiments, 36 lamps 350 may be provided in the lead unit 300.

The lamp plate 310 may include a metal material including aluminum (Al) or nickel (Ni). However, the material of the lamp plate 310 is not limited thereto, and may also include other rigid materials.

According to embodiments, the lamp plate 310 may have a disk shape when viewed in the vertical direction Z, but is not limited thereto, and the lamp plate 310 may have a polygonal shape when viewed in the vertical direction Z.

The lamp plate 310 may include a first surface 310_a, which is a lower surface thereof, facing the substrate W, a center hole 311, a lamp hole 312, and an edge hole 313. The center hole 311 may extend from an upper surface of the lamp plate 310 to a lower surface of the lamp plate 310, and may be at the center of the lamp plate 310. The center hole 311 may provide a path, through which the gas supplied from the gas supply line (refer to 410 in FIG. 1) passes. In some embodiments, the diameter of the center hole 311 may be about 61 mm. Herein, the term such as “about” may reflect amounts, sizes, orientations, or layouts that vary only in a small relative manner, and/or in a way that does not significantly alter the operation, functionality, or structure of certain elements. For example, a range from “about 0.1 to about 1” may encompass a range such as a 0% to 5% deviation around 0.1 and a 0% to 5% deviation around 1, especially if such deviation maintains the same effect as the listed range.

The lamp hole 312 may extend from the upper surface of the lamp plate 310 to the lower surface of the lamp plate 310, and may be apart from the center hole 311 in the first or second horizontal direction. A plurality of lamp holes 312 may be provided in the lamp plate 310. Each of the plurality of lamp holes 312 may provide a path, through which each of the plurality of lamps 350 passes. Accordingly, the number of lamp holes 312 of the lamp plate 310 may be equal to the number of lamps 350. In some embodiments, 36 lamp holes 312 may be provided in the lamp plate 310. In embodiments, the diameter of the lamp hole 312 may be less than the diameter of the center hole 311. In some embodiments, the diameter of the lamp hole 312 may be about 40 mm. The lamp 350 may be fixed by the lamp hole 312 of the lamp plate 310.

The edge hole 313 may extend from the upper surface of the lamp plate 310 to the lower surface of the lamp plate 310, and may be at the edge of the lamp plate 310. A plurality of edge holes 313 may be provided in the lamp plate 310. The plurality of edge holes 313 may provide paths, through which the plurality of connection members 360 pass, respectively. Accordingly, the number of edge holes 313 of the lamp plate 310 may be equal to the number of connection members 360. In some embodiments, six edge holes 313 may be provided while two adjacent edge holes 313 form an angle of about 60 degrees from the center of the lamp plate 310. In some embodiments, the diameter of the edge hole 313 may be about 5.5 mm.

The upper shower head plate 330 may include a metal material including aluminum (Al) or nickel (Ni). However, the material of the upper shower head plate 330 is not limited thereto, and may also include other rigid materials.

According to embodiments, the upper shower head plate 330 may have a disk shape when viewed in the vertical direction Z, but is not limited thereto, and the upper shower head plate 330 may have a polygonal shape when viewed in the vertical direction Z.

The upper shower head plate 330 may include a lower surface facing the substrate W, a second surface 330_b facing the lower surface of the upper shower head plate 330, a center hole 331, a lamp hole 332, and an edge hole 333. In some embodiments, the second surface 330_b of the upper shower head plate 330 may the upper surface of upper shower head plate 330.

The center hole 331 of the upper shower head plate 330 may extend from the upper surface of the upper shower head plate 330 to the lower surface of the upper shower head plate 330, and may be at the center of the upper shower head plate 330. A side surface of the center hole 331 of the upper shower head plate 330 may be on the same plane as a side surface of the center hole 311 of the lamp plate 310. The center hole 331 of the upper shower head plate 330 may provide a path, through which the gas having passed through the center hole 311 of the lamp plate 310 moves down in the vertical direction Z. In some embodiments, the diameter of the center hole 331 may be about 61 mm.

The lamp hole 332 of the upper shower head plate 330 may extend from the upper surface of the upper shower head plate 330 to the lower surface of the upper shower head plate 330, and may be apart from the center hole 331 in the first or second horizontal direction. A plurality of lamp holes 332 may be provided in the upper shower head plate 330. Each of the plurality of lamp holes 332 may provide a path, through which each of the plurality of lamps 350 passes. Accordingly, the number of lamp holes 332 of the upper shower head plate 330 may be equal to the number of lamps 350. The side surface of each of the lamp holes 332 of the upper shower head plate 330 may be on the same plane as the side surface of each of the lamp holes 312 of the lamp plate 310. For example, the lamp 350 passing through one lamp hole 312 of the lamp plate 310 may pass through the lamp hole 332 of the upper shower head plate 330 having the same center as the lamp hole 312. In some embodiments, 36 lamp holes 332 may be provided in the upper shower head plate 330. In some embodiments, the diameter of the lamp hole 332 may be less than the diameter of the center hole 331. In some embodiments, the diameter of the lamp hole 333 may be about 40 mm.

The edge hole 333 of the upper shower head plate 330 may extend from the upper surface of the upper shower head plate 330 to the lower surface of the upper shower head plate 330, and may be at the edge of the upper shower head plate 330. A plurality of edge holes 333 may be provided in the upper shower head plate 330. The plurality of edge holes 333 may provide paths, through which the plurality of connection members 360 pass, respectively. Accordingly, the number of edge holes 333 of the upper shower head plate 330 may be equal to the number of connection members 360. The side surface of each of the edge holes 333 of the upper shower head plate 330 may be on the same plane as the side surface of each of the edge holes 313 of the lamp plate 310. For example, the connection member 360 passing through one edge hole 313 of the lamp plate 310 may pass through the edge hole 333 of the upper shower head plate 330 having the same center as the edge hole 313. According to embodiments, the edge holes 333 may be provided in six, while two adjacent edge holes 333 form an angle of about 60 degrees from the center of the upper shower head plate 330.

The shock absorbing plate 320 may be arranged between the lamp plate 310 and the upper shower head plate 330. The upper surface of the shock absorbing plate 320 may contact the first surface 310_a of the lamp plate 310, and the lower surface of the shock absorbing plate 320 may contact the second surface 330_b of the upper shower head plate 330.

The shock absorbing plate 320 may have a friction coefficient less than the friction coefficient of a material forming the surfaces of the lamp plate 310 and the upper shower head plate 330. Accordingly, even when the lamp plate 310 and the upper shower head plate 330 expand or contract according to the temperature change in the processing chamber 100 and cause friction between the upper and lower surfaces of the shock absorbing plate 320, due to the lower friction coefficient of the shock absorbing plate 320, occurrence of cracks and particles on the first surface 310_a of the lamp plate 310 and the second surface 330_b of the upper shower head plate 330 may be prevented.

The shock absorbing plate 320 may have an elastic modulus less than an elastic modulus of each of the lamp plate 310 and the upper shower head plate 330. A material having a low elastic modulus may be softer than a material having a high elastic modulus, and may have a longer time of receiving shock. Accordingly, when the shock amount is equal, the force applied to the shock absorbing plate 320 may decrease, and the force applied to the surfaces of the lamp plate 310 and the upper shower head plate 330, which acts as a reaction to the force, may also decrease. As a result, the friction force applied to the first surface 310_a of the lamp plate 310 and the second surface 330_b of the upper shower head plate 330 may be reduced, and thus, occurrence of cracks and particles on the first surface 310_a of the lamp plate 310 and the second surface 330_b of the upper shower head plate 330 may be prevented.

In addition, when compression stress in the vertical direction Z is applied to the shock absorbing plate 320 due to the low elastic modulus of the shock absorbing plate 320, more compression may occur in the vertical direction Z than on the lamp plate 310 and the upper shower head plate 330. Due to the compression in the vertical direction Z of the shock absorbing plate 320, an empty space between the first surface 310_a of the lamp plate 310 and the upper surface of the shock absorbing plate 320 may be reduced, and an empty space between the second surface 330_b of the upper shower head plate 330 and the lower surface of the shock absorbing plate 320 may be reduced.

In this manner, a space between the first surface 310_a of the lamp plate 310 and the second surface 330-b of the upper shower head plate 330, through which the gas leaks, may be blocked, and thus, the gas passing through the center of the lead unit 300 in the vertical direction Z may be prevented from leaking between the first surface 310_a of the lamp plate 310 and the second surface 330-b of the upper shower head plate 330.

The shock absorbing plate 320 may have a disk shape when viewed in the vertical direction Z, but is not limited thereto, and the shock absorbing plate 320 may have a polygonal shape when viewed in the vertical direction Z. According to embodiments, the shock absorbing plate 320 may, when viewed in the vertical direction Z, have the same shape as the lamp plate 310 and the upper shower head plate 330 when viewed in the vertical direction Z. According to embodiments, the shock absorbing plate 320 may have a cylindrical shape extending from an upper surface to a lower surface thereof.

The shock absorbing plate 320 may include a center hole 321, a lamp hole 322, and an edge hole 323.

The center hole 321 of the shock absorbing plate 320 may extend from the upper surface of the shock absorbing plate 320 to the lower surface of the shock absorbing plate 320, and may be at the center of the shock absorbing plate 320. A side surface of the center hole 321 of the shock absorbing plate 320 may be on the same plane as a side surface of the center hole 311 of the lamp plate 310. The center hole 321 of the shock absorbing plate 320 may provide a path, through which the gas having passed through the center hole 311 of the lamp plate 310 moves down in the vertical direction Z. In some embodiments, the diameter of the center hole 321 may be about 61 mm.

The shock absorbing plate 320 may include a material having a high acid resistance. According to embodiments, the shock absorbing plate 320 may include a material having an acid resistance to hydrogen fluoride (HF), but is not limited thereto. The gas passing through the center hole 321 may include, for example, HF. Because the HF has the property of an acid, the HF may corrode the periphery of the center hole 321. As the shock absorbing plate 320 includes an acid-resistant material, it may be possible to prevent the shock absorbing plate 320 from being corroded by the gas passing through the center hole 321.

The lamp hole 322 of the shock absorbing plate 320 may extend from the upper surface of the shock absorbing plate 320 to the lower surface of the shock absorbing plate 320, and may be apart from the center hole 321 in the first or second horizontal direction. A plurality of lamp holes 322 may be provided in the shock absorbing plate 320. Each of the plurality of lamp holes 322 may provide a path, through which each of the plurality of lamps 350 passes. Accordingly, the number of lamp holes 322 of the shock absorbing plate 320 may be equal to the number of lamps 350. The side surface of each of the lamp holes 322 of the shock absorbing plate 320 may be on the same plane as the side surface of each of the lamp holes 312 of the lamp plate 310. For example, the lamp 350 passing through one lamp hole 312 of the lamp plate 310 may pass through the lamp hole 322 of the shock absorbing plate 320 having the same center as the lamp hole 312. In some embodiments, 36 lamp holes 322 may be provided in the shock absorbing plate 320. In embodiments, the diameter of the lamp hole 322 may be less than the diameter of the center hole 321. In some embodiments, the diameter of the lamp hole 323 may be about 40 mm.

The shock absorbing plate 320 may include a material having a high heat resistance. According to embodiments, the shock absorbing plate 320 may include a material having heat resistance at temperatures of the processing chamber 100, in which the etching process is performed. According to embodiments, the shock absorbing plate 320 may including a material having heat resistance at about 300° C. In the shock absorbing plate 320, the periphery of the lamp hole 322 may be exposed to a high temperature environment by the lamp 350, which heats the substrate W. As the shock absorbing plate 320 includes a material having a strong heat resistance, it may be possible to prevent thermal deformation due to the lamp passing through the lamp hole 322 of the shock absorbing plate 320.

The edge hole 323 of the shock absorbing plate 320 extends from the upper surface of the shock absorbing plate 320 to the lower surface of the shock absorbing plate 320, and may be at the edge of the shock absorbing plate 320. A plurality of edge holes 323 may be provided in the shock absorbing plate 320. The plurality of edge holes 323 may provide paths, through which the plurality of connection members 360 pass, respectively. Accordingly, the number of edge holes 323 of the shock absorbing plate 320 may be equal to the number of connection members 360. The side surface of each of the edge holes 323 of the shock absorbing plate 320 may be on the same plane as the side surface of each of the edge holes 313 of the lamp plate 310. For example, the connection member 360 passing through one edge hole 313 of the lamp plate 310 may pass through the edge hole 323 of the shock absorbing plate 320 having the same center as the edge hole 313. According to embodiments, the edge holes 323 may be provided in six, while two adjacent edge holes 323 form an angle of about 60 degrees from the center of the shock absorbing plate 320.

A vertical thickness t₁ of the shock absorbing plate 320 may be in a range of about 1.4 mm to about 1.6 mm. When the vertical thickness t₁ of the shock absorbing plate 320 is in a range of 1.4 mm to 1.6 mm, the shock absorbing plate 320 may be stably manufactured and an effect on the etching process may be reduced by increasing a length of the lead unit 300 in the vertical direction Z.

According to embodiments, the shock absorbing plate 320 may include a material including polytetrafluoroethylene (PTFE) or polyimide (PI) for satisfying a friction coefficient, an elastic modulus, acid resistance, and heat resistance, but is not limited thereto.

In addition, in FIGS. 1 through 3, the shock absorbing plate 320 is illustrated as being between the lamp plate 310 and the upper shower head plate 330, but is not limited thereto, and the shock absorbing plate 320 may be between any two stacked plates in the processing chamber 100, in which the heat treatment process is performed.

The lower shower head plate 340 may include a metal material including aluminum (Al) or nickel (Ni). However, the material of the lower shower head plate 340 is not limited thereto, and may also include other rigid materials.

According to embodiments, the lower shower head plate 340 may have a disk shape when viewed in the vertical direction Z, but is not limited thereto, and the lower shower head plate 340 may have a polygonal shape when viewed in the vertical direction Z.

The lower shower head plate 340 may include a center hole 341, a lamp hole 342, an edge hole 343, and a spray hole 344.

The center hole 341 may extend from an upper surface of the lower shower head plate 340 to a lower surface of the lower shower head plate 340, and may be at the center of the lower shower head plate 340. The side surface of the center hole 341 of the lower shower head plate 340 may be on the same plane as the side surfaces of the center hole 311 of the lamp plate 310 and the center hole 331 of the upper shower head plate 330. The center hole 341 of the lower shower head plate 340 may provide a path, through which gas having passed through the center hole 331 of the upper shower head plate 330 is supplied onto the substrate W. In some embodiments, the diameter of the center hole 341 may be about 61 mm.

The lamp hole 342 of the lower shower head plate 340 may extend from the upper surface of the lower shower head plate 340 to the lower surface of the lower shower head plate 340, and may be apart from the center hole 341 in the first or second horizontal direction. A plurality of lamp holes 342 may be provided in the lower shower head plate 340. Each of the plurality of lamp holes 342 may provide a path, through which each of the plurality of lamps 350 passes. Accordingly, the number of lamp holes 342 of the lower shower head plate 340 may be equal to the number of lamps 350. The side surface of each of the lamp holes 342 of the upper shower head plate 330 may be on the same plane as the side surface of each of the lamp holes 312 of the lamp plate 310. For example, the lamp 350 passing through one lamp hole 312 of the lamp plate 310 may pass through the lamp hole 342 of the lower shower head plate 340 having the same center as the lamp hole 312. In some embodiments, 36 lamp holes 342 may be provided. In embodiments, the diameter of the lamp hole 342 may be less than the diameter of the center hole 341. In some embodiments, the diameter of the lamp hole 342 may be about 40 mm.

The edge hole 343 of the lower shower head plate 340 may extend from the upper surface of the lower shower head plate 340 to the lower surface of the lower shower head plate 340, and may be at the edge of the lower shower head plate 340. A plurality of edge holes 343 may be provided in the lower shower head plate 340. The plurality of edge holes 343 may provide paths, through which the plurality of connection members 360 pass, respectively. Accordingly, the number of edge holes 343 of the lower shower head plate 340 may be equal to the number of connection members 360. The side surface of each of the edge holes 343 of the lower shower head plate 340 may be on the same plane as the side surface of each of the edge holes 313 of the lamp plate 310. For example, the connection member 360 passing through one edge hole 313 of the lamp plate 310 may pass through the edge hole 343 of the lower shower head plate 340 having the same center as the edge hole 313. According to embodiments, the edge holes 343 may be provided in six, while two adjacent edge holes 343 form an angle of about 60 degrees from the center of the lower shower head plate 340.

The spray hole 344 may include an opening formed in the lower surface of the lower shower head plate 340. A plurality of spray holes 344 may be provided in the lower shower head plate 340, and may be uniformly formed on the lower surface of the lower shower head plate 340. In some embodiments, the spray hole 344 may have a cylindrical shape extending from the lower surface of the lower shower head plate 340 toward the substrate W. The gas having passed through the center hole 341 of the lower shower head plate 340 may be evenly sprayed onto the substrate W by using a plurality of spray holes 344.

The connection members 360 may be configured to combine the lower shower head plate 340, the upper shower head plate 330, the shock absorbing plate 320, and the lamp plate 310. According to embodiments, each connection member 360 may include a bolt 361 and a nut 363. The bolt 361 may include a head and a body. The connection member 360 may include any pillar or rod-shaped component that passes through the various plates and that is configured to be secured to the plates. In this manner, the connection member 360 may include a rod or pillar secured by two nuts or other removable or non-removable fastening pieces (e.g., a clip or stud), configured to secure and hold together the various plates, or a bolt secured by a nut or other removable or non-removable fastening piece.

The head of the bolt 361 may contact the lower surface of the lower shower head plate 340, and the body of the bolt 361 may sequentially penetrate the edge hole 343 of the lower shower head plate 340, the edge hole 333 of the upper shower head plate 330, the edge hole 323 of the shock absorbing plate 320, and the edge hole 313 of the lamp plate 310, and may be combined with a nut on the upper surface of the upper shower head plate 330. Accordingly, the connection member 360 may be configured to combine the lower shower head plate 340, the upper shower head plate 330, the shock absorbing plate 320, and the lamp plate 310.

By combining the lamp plate 310, the shock absorbing plate 320, the upper shower head plate 330, and the lower shower head plate 340 by using the connection member 360, the center holes 311, 321, 331, and 341 of the lamp plate 310, the shock absorbing plate 320, the upper shower head plate 330, and the lower shower head plate 340 may be aligned to each other, respectively, and a path, through which the gas supplied from the gas supply line (refer to 410 in FIG. 1) passes, may be provided. For example, the gas supplied from the gas supply line (refer to 410 in FIG. 1) may pass through the lead unit 300 in the direction of an arrow in FIG. 2 from the center of the lead unit 300, and may be uniformly sprayed onto the substrate W by the spray hole 344.

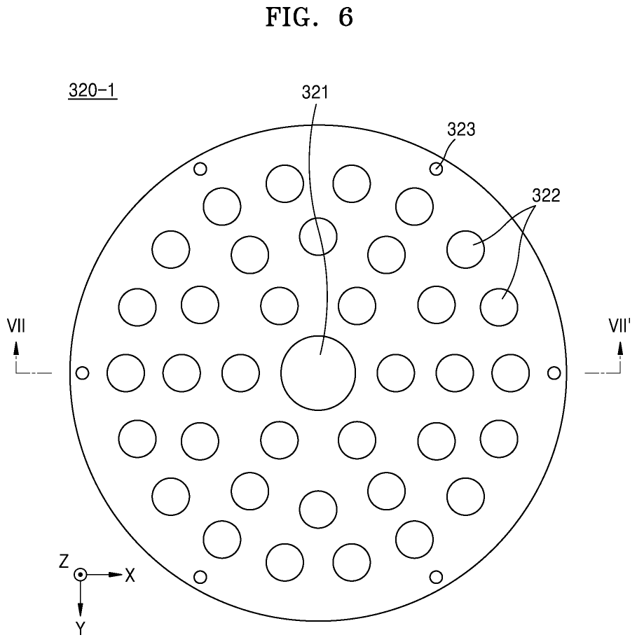

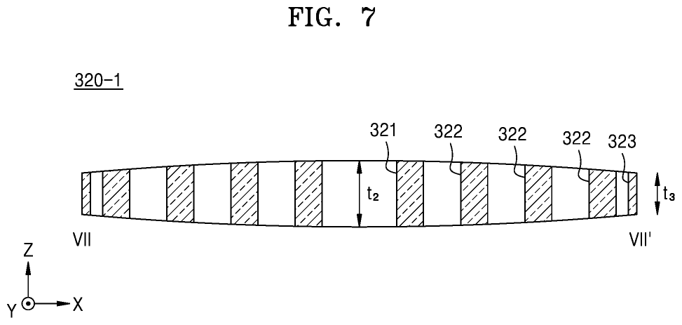

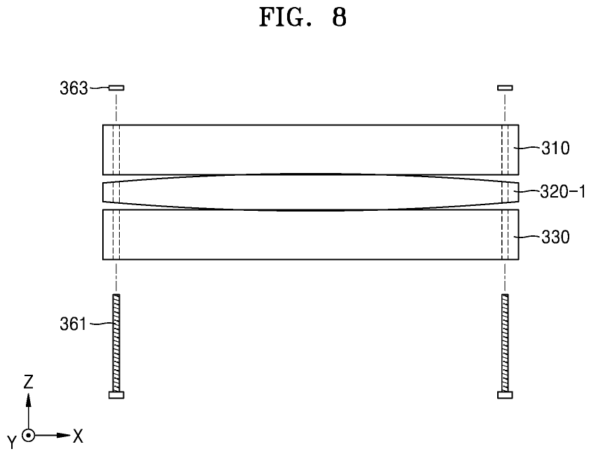

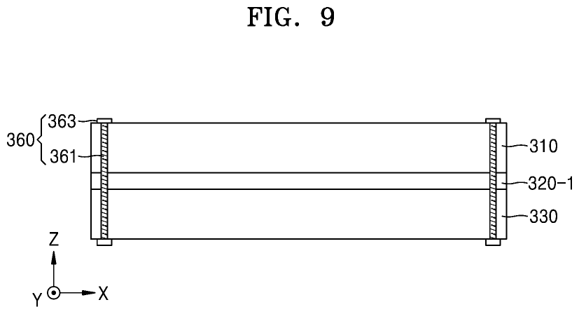

FIG. 6 is a plan view of a shock absorbing plate 320-1 of the substrate processing apparatus 10, according to an embodiment. FIG. 7 is a cross-sectional view of the shock absorbing plate 320-1 taken along line VII-VII′ in FIG. 6 according to an embodiment. FIGS. 8 and 9 are schematic diagrams of the shock absorbing plate 320-1 according to example embodiments.

Hereinafter, duplicate descriptions of the shock absorbing plate 320 of FIG. 4 and the shock absorbing plate 320-1 of FIG. 6 are omitted and differences thereof are mainly described.

Referring to FIGS. 6 through 9, the shock absorbing plate 320-1 may include the center hole 321, the lamp hole 322, and the edge hole 323.

The shock absorbing plate 320-1 may have a circular shape when viewed from the vertical direction Z, and a vertical thickness of the shock absorbing plate 320-1 may be the largest at the center and may be decreased from the center toward an outer edge thereof. According to embodiments, the shock absorbing plate 320-1, when no pressure is applied thereto, may have an elliptical shape, or a convex shape, when viewed from the side surface.

According to embodiments, the connection member (refer to 360 in FIG. 2) may include the bolt 361 and the nut 363. The bolt 361 may penetrate the edge hole 323 at the edge of the shock absorbing plate 320-1, and may be combined to the nut 363 on the upper surface of the lamp plate 310. The shock absorbing plate 320-1 may be combined between the lamp plate 310 and the upper shower head plate 330 by using the combination of the bolt 361 and the nut 363. In this case, the shock absorbing plate 320-1 may be subject to the greatest vertical stress at the edge, where the edge hole 323 is arranged. However, because the shock absorbing plate 320-1 according to the present embodiment has the vertical thickness that is the largest at the center and decreases from the center toward the outer edge, a vertical stress may be applied first to the center of the shock absorbing plate 320-1. Accordingly, the shock absorbing plate 320-1 may have the greatest elastic shrinkage at the center and the smallest at the edge on the periphery of the edge hole 323. For example, because the shock absorbing plate 320-1 has the smallest elastic contraction at the edge, at which the strongest vertical stress is applied, it may be possible to prevent the shock absorbing plate 320-1 from reaching the yielding point, at which permanent deformation occurs.

In addition, because the shock absorbing plate 320-1 has the most elastic shrinkage in the thickness in the vertical direction at the center thereof, when the shock absorbing plate 320-1 is combined between the lamp plate 310 and the upper shower head plate 330, the upper shower head plate 330 may have a flat shape as illustrated in FIG. 9. Because the density of the shock absorbing plate 320-1 is largest at the center thereof, it may be possible to prevent the gas passing through the lead unit 300 from leaking in the horizontal direction.

A vertical thickness t₂ at the center of the shock absorbing plate 320-1 may be in the range of about 1.4 mm to about 1.6 mm, and a vertical thickness t₃ at the end of the shock absorbing plate 320-1 may be in the range of about 1.3 mm to about 1.4 mm.

When the vertical thickness t₂ at the center of the shock absorbing plate 320-1 and the vertical thickness t₃ at the end are within the above ranges, the shock absorbing plate 320-1 may be stably manufactured, and the effect on the etching process may be reduced by increasing the length of the lead unit 300 in the vertical direction Z.

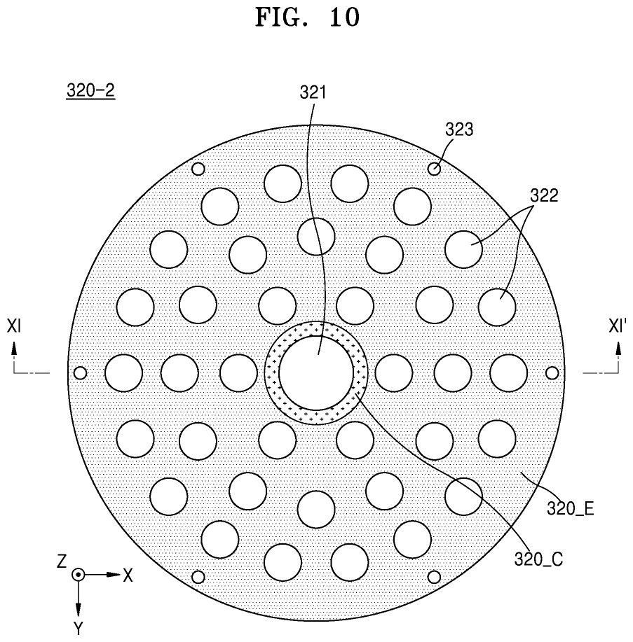

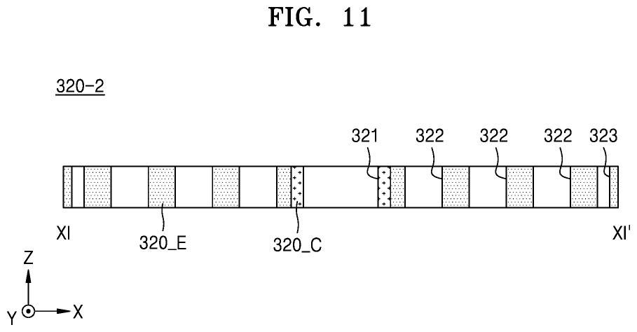

FIG. 10 is a plan view of a shock absorbing plate 320-2 of the substrate processing apparatus 10, according to an embodiment. FIG. 11 is a cross-sectional view of the shock absorbing plate 320-2 taken along line XI-XI′ in FIG. 10 according to an embodiment.

Hereinafter, duplicate descriptions of the shock absorbing plate 320 of FIG. 4 and the shock absorbing plate 320-2 of FIG. 10 are omitted and differences thereof are mainly described.

Referring to FIGS. 10 and 11, the shock absorbing plate 320-2 may include the center hole 321, the lamp hole 322, the edge hole 323, a first portion 320_C, and a second portion 320_E.

In example embodiments, the first portion 320_C of the shock absorbing plate 320-2 may be arranged at the center portion of the shock absorbing plate 320-2 and the second portion 320_E of the shock absorbing plate 320-2 may be arranged at the periphery portion of the shock absorbing plate 320-2. For example, the first portion 320_C may surround the center hole 321 and the second portion 320_E may surround the plurality of lamp holes 322 and the edge holes 323.

The first portion 320_C and the second portion 320_E of the shock absorbing plate 320-2 may include different materials from each other. According to embodiments, the elastic modulus of a material constituting the first portion 320_C, which is the center portion of the shock absorbing plate 320-2, may be less than the elastic modulus of a material constituting the second portion 320_E, which is the outer portion of the shock absorbing plate 320-2.

According to embodiments, the material constituting the first portion 320_C, which is the center portion of the shock absorbing plate 320-2, may include a material with strong acid resistance and heat resistance.

A periphery of the center hole 321 of the shock absorbing plate 320-2 may be exposed to an acid and may have a high-temperature environment. Accordingly, when the first portion 320_C of the shock absorbing plate 320-2 includes a material having strong acid resistance and heat resistance, a cycle of replacing the shock absorbing plate 320-2 may be increased, and the lamp plate 310 and the upper shower head plate 330 may be more effectively protected from shock.

According to embodiments, the shock absorbing plate 320-2 may include an O-ring in the first portion 320_C, which is the center portion thereof, and the O-ring may include a perfluoro elastomer (FFKM) O-ring, but is not limited thereto.

While the inventive concept has been particularly shown and described with reference to embodiments thereof, it will be understood that various changes in form and details may be made therein without departing from the spirit and scope of the following claims.

What is claimed is:

1. A substrate processing apparatus comprising:
a substrate support configured to support a substrate;
a lamp plate including a lower surface facing the substrate, an upper surface opposite to the lower surface of the lamp plate, and a plurality of lamps configured to heat the substrate;
a shock absorbing plate including an upper surface contacting the lower surface of the lamp plate and a lower surface opposite to the upper surface of the shock absorbing plate;
an upper shower head plate including an upper surface contacting the lower surface of the shock absorbing plate and a lower surface facing the upper surface of the upper shower head plate; and
a lower shower head plate including an upper surface contacting the lower surface of the upper shower head plate, a lower surface opposite to the upper surface of the lower shower head plate and facing the substrate, and a plurality of spray holes configured to supply a gas onto the substrate,
wherein the shock absorbing plate is configured to absorb a shock between the lamp plate and the upper shower head plate in a vertical direction, and
wherein each of the lamp plate, the shock absorbing plate, the upper shower head plate, and the lower shower head plate further includes:
a center hole configured to pass the gas,
a plurality of lamp holes configured to allow a plurality of lamps to pass therethrough, respectively, and
a plurality of edge holes configured to allow a plurality of connection members to pass therethrough, respectively,
wherein the plurality of connection members are configured to hold together the lamp plate, the shock absorbing plate, the upper shower head plate, and the lower shower head plate, and
wherein each hole of the center hole, the plurality of lamp holes, and the plurality of edge holes extends from an upper surface to a lower surface of a corresponding plate.

2. The substrate processing apparatus of claim 1, wherein a friction coefficient of the shock absorbing plate is less than a friction coefficient of each of the lamp plate and the upper shower head plate, and
wherein an elastic modulus of the shock absorbing plate is less than an elastic modulus of each of the lamp plate and the upper shower head plate.

3. The substrate processing apparatus of claim 1, wherein a vertical thickness of the shock absorbing plate is in a range of about 1.4 mm to about 1.6 mm.

4. The substrate processing apparatus of claim 1, wherein a vertical thickness of the shock absorbing plate is largest at a center thereof and decreases from the center toward an edge of the shock absorbing plate.

5. The substrate processing apparatus of claim 4, wherein the shock absorbing plate has an elliptical shape when viewed from a side surface of the shock absorbing plate.

6. The substrate processing apparatus of claim 5, wherein when no pressure is applied to the shock absorbing plate:
the vertical thickness of the shock absorbing plate at the center of the shock absorbing plate is in a range of about 1.4 mm to about 1.6 mm, and
a vertical thickness of the shock absorbing plate at the edge of the shock absorbing plate is in a range of about 1.3 mm to about 1.4 mm.

7. The substrate processing apparatus of claim 1, wherein a material constituting the shock absorbing plate comprises polyimide (PI) or polytetrafluoroethylene (PTFE).

8. The substrate processing apparatus of claim 1, wherein the shock absorbing plate further includes a first portion surrounding the center hole of the shock absorbing plate and a second portion surrounding the plurality of lamp holes and the edge holes of the shock absorbing plate, and
wherein the first portion of the shock absorbing plate is formed of a material different from a material of the second portion of the shock absorbing plate.

9. The substrate processing apparatus of claim 1, wherein each of the connection members comprises a bolt and a nut.

10. A substrate processing apparatus comprising;
a first plate;
a shock absorbing plate under the first plate;
a second plate under the shock absorbing plate;
wherein the shock absorbing plate comprises:
a plurality of holes configured to penetrate the shock absorbing plate in a vertical direction,
wherein the shock absorbing plate is configured to absorb a shock between the first plate and the second plate in the vertical direction,
wherein the first plate is apart from the second plate in the vertical direction,
wherein the shock absorbing plate has a circular shape when viewed in the vertical direction,
wherein a vertical thickness of the shock absorbing plate at a center thereof, when pressure is not applied to the shock absorbing plate, is greatest and decreases from the center toward an edge thereof,
wherein a friction coefficient of the shock absorbing plate is less than a friction coefficient of each of the first plate and the second plate, and
wherein an elastic modulus of the shock absorbing plate is less than an elastic modulus of the first plate and the second plate.

11. The substrate processing apparatus of claim 10, wherein the plurality of holes of the shock absorbing plate comprise:
a center hole configured to pass a gas,
a plurality of lamp holes configured to pass a plurality of lamps, and
a plurality edge holes configured to pass a plurality of connection members,
wherein plurality of lamps are configured to heat a substrate, and
wherein the plurality of connection members are configured to hold together the first plate, the shock absorbing plate, and the second plate.

12. The substrate processing apparatus of claim 11, wherein the shock absorbing plate includes a first portion surrounding the center hole of the shock absorbing plate and a second portion surrounding the plurality of lamp holes and edge holes of the shock absorbing plate, and
wherein the first portion of the shock absorbing plate is formed of a material different from a material of the second portion of the shock absorbing plate.

13. The substrate processing apparatus of claim 12, wherein the first portion of the shock absorbing plate, comprises an O-ring.

14. The substrate processing apparatus of claim 10, wherein a material constituting the shock absorbing plate has acid resistance to hydrogen fluoride (HF).

15. The substrate processing apparatus of claim 10, wherein a material constituting the shock absorbing plate has heat resistance at 300° C.

16. The substrate processing apparatus of claim 10, wherein a vertical thickness of the shock absorbing plate at the center of the shock absorbing plate, when no pressure is applied to the shock absorbing plate, is in a range of about 1.4 mm to about 1.6 mm, and
wherein a vertical thickness of the shock absorbing plate at the edge of the shock absorbing plate, when no pressure is applied to the shock absorbing plate, is in a range of about 1.3 mm to about 1.4 mm.

17. The substrate processing apparatus of claim 10, wherein a material constituting the shock absorbing plate comprises a polyimide (PI) or polytetrafluoroethylene (PTFE) material.

18. A substrate processing apparatus comprising:
a processing chamber configured to provide a space for processing a substrate;
a substrate support configured to support the substrate;
a lamp plate including a lower surface facing a top surface of the substrate support, an upper surface opposite the lower surface of the lamp plate, and a plurality of lamps configured to heat the substrate;
a shock absorbing plate including an upper surface contacting the lower surface of the lamp plate and a lower surface opposite the upper surface of the shock absorbing plate;
an upper shower head plate including an upper surface contacting the lower surface of the shock absorbing plate and a lower surface opposite the upper surface of the upper shower head plate; and
a lower shower head plate including an upper surface contacting the lower surface of the upper shower head plate, a lower surface opposite the upper surface of the lower shower head plate and the substrate, and a plurality of spray holes configured to supply a gas onto the substrate,
wherein a friction coefficient of the shock absorbing plate is less than a friction coefficient of each of the lamp plate and the upper shower head plate, and
wherein an elastic modulus of the shock absorbing plate is less than an elastic modulus of each of the lamp plate and the upper shower head plate,
wherein the shock absorbing plate is configured to absorb a shock between the lamp plate and the upper shower head plate in a vertical direction, and
wherein a vertical thickness of the shock absorbing plate at a center thereof, when no pressure is applied to the shock absorbing plate, is greatest and decreases from the center toward an edge thereof.

19. The substrate processing apparatus of claim 18, wherein a material constituting the shock absorbing plate comprises a polyimide (PI) or polytetrafluoroethylene (PTFE) material.

20. The substrate processing apparatus of claim 18, wherein, when no pressure is applied to the shock absorbing plate:
the vertical thickness of the shock absorbing plate at a center of the shock absorbing plate is in a range of about 1.4 mm to about 1.6 mm, and
a vertical thickness of the shock absorbing plate at an edge of the shock absorbing plate is in a range of about 1.3 mm to about 1.4 mm.
